(19) United States
(12) Patent Application Publication
(10) Pub. No.: US 2021/0136957 A1
(43) Pub. Date: May 6, 2021

(54) HEAT DISSIPATION DEVICE

(71) Applicants: INVENTEC (PUDONG) TECHNOLOGY CORPORATION, Shanghai City (CN); INVENTEC CORPORATION, Taipei City (TW)

(72) Inventors: Shuaifeng ZHU, Shanghai City (CN); Pin-Yi XIANG, Shanghai City (CN); Lian-Fei ZHANG, Shanghai City (CN)

(73) Assignees: INVENTEC (PUDONG) TECHNOLOGY CORPORATION, Shanghai City (CN); INVENTEC CORPORATION, Taipei City (TW)

(21) Appl. No.: 16/688,346

(22) Filed: Nov. 19, 2019

(30) Foreign Application Priority Data
Oct. 30, 2019 (CN) 201911046409.6

(51) Int. Cl. H05K 7/20; F28F 3/02

(52) U.S. Cl. CPC H05K 7/20409; F28D 15/02; F28F 3/02

(57) ABSTRACT

The disclosure provides a heat dissipation device. The heat dissipation device is configured to dissipate heat generated by a central process unit. The heat dissipation device includes a first heat dissipation component, at least one second heat dissipation component and at least one heat pipe. The at least one heat pipe is connected to the first heat dissipation component and the at least one second heat dissipation component, the first heat dissipation component is configured to be correspondingly disposed at a side of the central processing unit.

### CROSS-REFERENCE TO RELATED APPLICATIONS

This non-provisional application claims priority under 35 U.S.C. § 119(a) on Patent Application No(s). 201911046409.6 filed in China on Oct. 30, 2019 the entire contents of which are hereby incorporated by reference.

### BACKGROUND OF THE INVENTION

### Technical Field of the Invention

The disclosure relates to the field of heat dissipation, particularly relates to a heat dissipation device.

### Description of the Related Art

With the development of electronic products, the electronic products are required to provide more diversity functions to users. To achieve these functions, there are more and more chips integrated in the electronic product, resulting in high internal temperature at a few particular areas. Heat generated by these heat sources needs to be dissipated rapidly to ensure the performance. Take a central process unit (CPU) of a server system as an example, a well-functioned heat dissipation device is necessary to improve the stability and reliability of the server system, or the electronic product may breakdown as the temperature of CPU exceeds the threshold value.

Generally, there are two types of heat dissipation device—fan and heat dissipation assembly. The heat dissipation assembly achieves heat dissipation by the following approaches: 1) using graphite sheets or copper foil but which have very limited heat conduction efficiency; or 2) using heat pipe but which is not effective due to the single thermal transferring direction of the heat pipe. As can be seen, a high-efficiency heat dissipation device becomes a hot topic in the field.

On the other hand, the mainstream heat dissipation devices for server are mainly manufactured by Intel, their heat dissipation devices are required to be installed nearby CPU and cooperated with fan that can blow heat away.

### SUMMARY OF THE INVENTION

One embodiment of the disclosure provides a heat dissipation device. The heat dissipation device is configured to dissipate heat generated by a central process unit. The heat dissipation device includes a first heat dissipation component, at least one second heat dissipation component and at least one heat pipe. The at least one heat pipe is connected to the first heat dissipation component and the at least one second heat dissipation component, the first heat dissipation component is configured to be correspondingly disposed at a side of the central processing unit.

### BRIEF DESCRIPTION OF THE DRAWINGS

The present disclosure will become more fully understood from the detailed description given hereinbelow and the accompanying drawings which are given by way of illustration only and thus are not limitative to the present disclosure and wherein:

FIG. 1 is a schematic view of a conventional heat dissipation device; and

FIG. 2 is a schematic view of a heat dissipation device according to one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the following embodiments are disclosed by the figures, and some practical details are described in the following paragraphs, but the present disclosure is not limited thereto. Furthermore, for the purpose of illustration, some of the structures and components in the figures are simplified, and wires, reference lines or buses are omitted in some of the figures.

Moreover, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

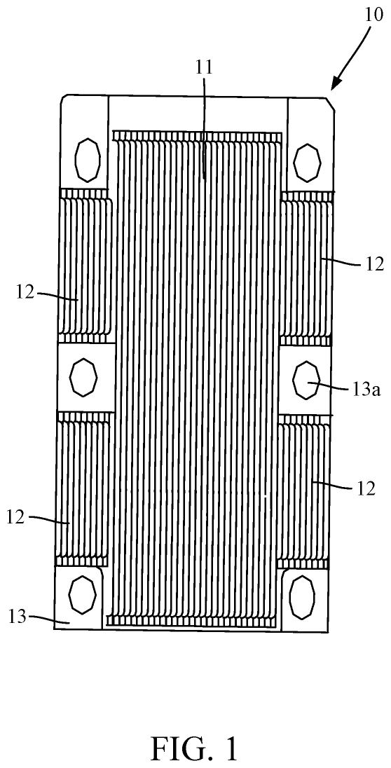

As discussed in the related art above, FIG. 1 depicts a schematic view of a conventional heat dissipation device 10. As shown in FIG. 1, the heat dissipation device 10 is one of the mainstream server heat dissipation devices manufactured by Intel. The heat dissipation device 10 includes a main heatsink 11 and four sub-heatsinks 12. The cross-sectional surface of the main heatsink 11 is in a rectangular shape. The four sub-heatsink 12 are respectively and symmetrically disposed on two opposite sides of the main heatsink 11. The sub-heatsink 12 and the main heatsink 11 extend toward the same direction. There are two sub-heatsinks 12 on either side of the main heatsink 11, where the two sub-heatsinks 12 are disposed apart from each other and located between two opposite ends of the main heatsink 11, such that there are three recesses formed at either side of the main heatsink 11. The heat dissipation device 10 further includes a casing 13. The main heatsink 11 and the sub-heatsink 12 are fixed on the same surface of the casing 13. The casing 13 has a plurality of through holes 13a respectively located at these recesses. These through holes 13a are used for the heat dissipation device 10 to be fixed to fixing structure nearby CPU, such that the heat dissipation device 10 then can dissipate heat generated by the CPU. The heat dissipation device 10 is merely located nearby the CPU and thus not using the available space around the CPU, limiting the heat dissipation capability to the CPU. As a result, it needs to speeds up the fan to enhance the heat dissipation, but which increases energy consumption. In addition, as the server is subjected to impact, the heat dissipation device 10 is easily deformed and damaged due to its weak structural strength. This may decrease the heat dissipation efficiency of the heat dissipation device 10. Consequently, the fan needs to operate at a higher speed and thus increasing energy consumption.

Accordingly, the disclosure provides a heat dissipation device, and the heat dissipation device includes a first heat dissipation component, at least one second heat dissipation component and at least one heat pipe. The heat pipe is connected to the first heat dissipation component and the second heat dissipation component. The first heat dissipation component is correspondingly disposed on a side of the CPU. In the disclosure, since the heat pipe is connected to the first heat dissipation component and the second heat dissipation component, such that the heat pipe is able to transmit at least part of heat on the first heat dissipation component to the second heat dissipation component, increasing the heat dissipation area of the heat dissipation device and thereby increasing the heat dissipation efficiency of the heat dissipation device to the central process unit. Therefore, there is no need to speed up the fan and thus saving energy.

Furthermore, a casing of the heat dissipation device has side walls located at recesses of the first heat dissipation component, such that the side walls of the casing increase the structural strength of the heat dissipation device to prevent the heat dissipation device from being deformed while subjected to impact, thereby avoiding affecting the heat dissipation efficiency of the heat dissipation device due to the deformation issue.

The following paragraphs will further discuss the heat dissipation device of the disclosure. The detail descriptions in the following paragraphs is cooperated with drawings, and the preferable embodiment of the disclosure is illustrated. It is understood that a person skilled in the art can amend the disclosure and still obtain the same effect and benefit, thus the following descriptions should be considered as a broad understanding of this technical field and is not restricted to the disclosure.

For the purpose of illustration, the following description will not discuss the well-known functions and the structures in detail in order to prevent the disclosure from being confused by unnecessary details. It should be understood that in the development of any actual embodiment, a large number of implementation details must be made to achieve a particular goal of the developer, such as changing from one embodiment to another in accordance with the system limitations or the related commercial limitations. Additionally, such development work should be considered complex and time consuming, but it is only routine work for those skilled in the art.

In order to clearly illustrate the purpose and the features of the disclosure, the following descriptions are cooperated with drawings. Note that the drawings are simplified to be easily understood the purpose of the embodiment of the disclosure, thus the drawings may be made with inaccurate scale.

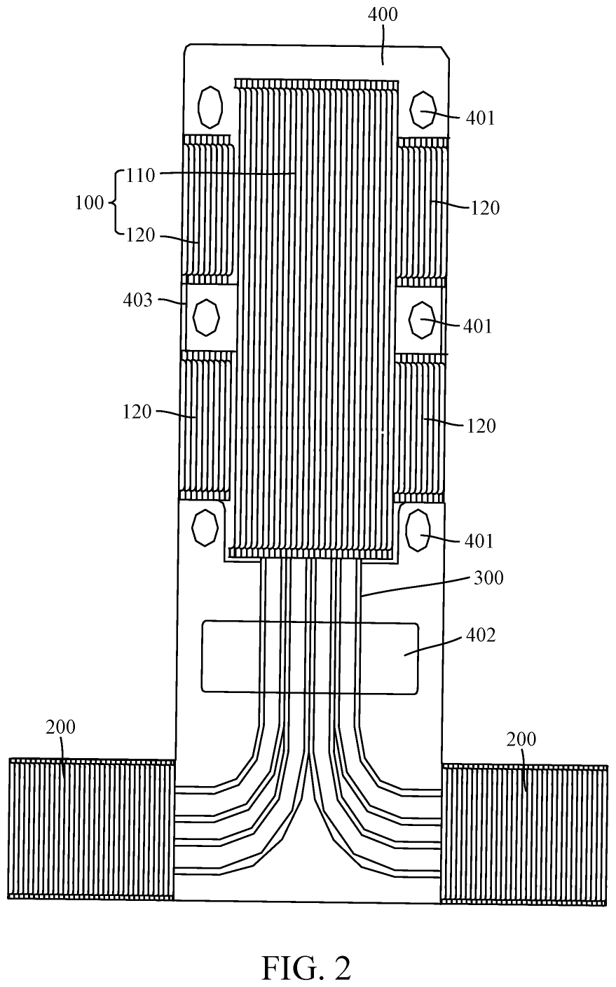

This embodiment provides a heat dissipation device, referring to FIG. 2, FIG. 2 is a schematic view of a heat dissipation device according to one embodiment of the disclosure. As shown in FIG. 2, the heat dissipation device is configured to be cooperated with a fan to dissipate heat generated by CPU. The heat dissipation device includes a first heat dissipation component 100, at least one second heat dissipation component 200, at least one heat pipe 300, and a casing 400. The heat pipe 300 connects the first heat dissipation component 100 with the second heat dissipation component 200. The first heat dissipation component 100, the second heat dissipation component 200 and the heat pipe 300 are fixed on the casing 400.

The first heat dissipation component 100 is correspondingly disposed on a side of the CPU for dissipating heat generated by the CPU. The first heat dissipation component 100 includes a main heat dissipation part 110 and at least one sub heat dissipation part 120. As an exemplary embodiment, the first heat dissipation component 100 includes one main heat dissipation part 110 and four sub heat dissipation parts 120. The cross-sectional surface of the main heat dissipation part 110 is, for example, in a quadrilateral shape, more specifically to a rectangular shape. The main heat dissipation part 110, for example, includes a plurality of first fins which are arranged side by side. The first fins are made of a thermally conductive material. The main heat dissipation part 110 has two opposite ends at an extension direction of the first fins. The cross-sectional surface of each sub heat dissipation part 120 is, for example, in a quadrilateral shape, more specifically to a rectangular shape. Each of the sub heat dissipation parts 120 includes a plurality of second fins which are arranged side by side. The second fins are made of a thermally conductive material. Lengths of the second fins along its extension direction are shorter than the lengths of the first fins along its extension direction. The first fins and the second fins extend toward the same extension direction, and the first fins and the second fins are arranged along the same direction. In the arrangement direction of the first fins, the four sub heat dissipation parts 120 are disposed on two opposite sides of the main heat dissipation part 110, such that there are two sub heat dissipation parts 120 located at either side of the main heat dissipation part 110 along the arrangement direction of the first fins, where the two sub heat dissipation parts 120 are spaced apart from each other and located between the two opposite ends of the main heat dissipation part 110. As such, there are three recesses formed at either side of the main heat dissipation part 110. It is understood that there are a total of six recesses defined by the sub heat dissipation parts 120 and the main heat dissipation part 110 and located at the two opposite sides of the main heat dissipation part 110.

In some other embodiments, the cross-sectional surfaces of the main heat dissipation part 110 and the sub heat dissipation part 120 may be modified to be circular, polygonal or other shapes according to an actual requirement. In addition, the quantity of the sub heat dissipation parts 120 may be modified to be one, two, three, five, etc. according to an actual requirement.

The second heat dissipation component 200 includes a plurality of third fins which are arranged side by side, and the third fins are made of a thermally conductive material. Preferably, the first fins, the second fins, and the third fins may be made of the same material, such as aluminum alloy. The quantity of the second heat dissipation component 200 is at least one. The cross-sectional surface of the second heat dissipation component 200 may be in a regular shape, such as a quadrilateral shape, a circular shape, a polygonal shape, or an irregular shape. The shape of the cross-sectional surface of the second heat dissipation component 200 can be determined according to the place, where it is installed, and the actual requirements. In one exemplary embodiment, the heat dissipation device includes two second heat dissipation components 200, where the cross-sectional surface of each second heat dissipation component 200 is, for example, in a rectangular shape.

The heat pipe 300 has two ends. The two ends of the heat pipe 300 are respectively connected to the first heat dissipation component 100 and the second heat dissipation component 200. The heat pipe 300 is able to transmit at least part of heat on the first heat dissipation component 100 to the second heat dissipation component 200, increasing the heat dissipation area of the heat dissipation device and thereby increasing the heat dissipation efficiency of the heat dissipation device to the CPU. Therefore, there is no need to speed up the fan and thus saving energy. In the case of more than one second heat dissipation component 200, the heat pipes 300 respectively connected to the second heat dissipation components 200 are separated at positions where they are connected to the first heat dissipation component 100. For example, the first heat dissipation component 100 is connected to one second heat dissipation component 200 via four heat pipes 300. It is understood that the first heat dissipation component 100 is connected to two second heat dissipation component 200 via eight heat pipes 300.

Along thickness directions of the first heat dissipation component 100 and the second heat dissipation component 200, the casing 400 is disposed on the same side with respect to the first heat dissipation component 100 and the second heat dissipation component 200. In other words, the first heat dissipation component 100 and the second heat dissipation component 200 are fixe on a same surface of the casing 400. The shape of the casing 400 may be determined according to the place where the casing is disposed and the actual requirements. In the case that the place for the placement of the casing 400 is in a shape with two ends, such as I shape, L shape, U shape, or S shape, the casing 400 may preferably have a mating shape. In such a case, the heat dissipation device includes only one second heat dissipation component 200, and the first heat dissipation component 100 and the second heat dissipation component 200 are respectively disposed on two ends of the casing 400, and the heat pipe 300 is located between the two ends of the casing 400; in the case that the place for the placement of the casing 400 is in a shape with three ends, such as λ shape, T shape, or E shape, the casing 400 may preferably have a mating shape; in such a case, the heat dissipation device includes two second heat dissipation components 200, the first heat dissipation component 100 and the two second heat dissipation components 200 are respectively disposed on three ends of the casing 400, and the heat pipes 300 are located among the three ends of the casing 400 and form a λ shape. Therefore, according to the above discussions, it is understood that: when the place for the placement of the casing 400 has k (k≥2) ends, the quantity of the second heat dissipation component 200 is k−1, and the first heat dissipation component 100 and the k−1 second heat dissipation components 200 are respectively disposed on the k ends of the casing 400, and the heat pipes 300 are located between the k ends of the casing 400.

The following table shows the difference between the power consumptions of the heat dissipation device of this embodiment and the conventional heat dissipation device, where the casing of the heat dissipation device of this embodiment is in a T shape, the heat dissipation device of this embodiment is also in T shape, and the heat dissipation device includes two second heat dissipation components 200.

| | | Power | Power | |
|---|---|---|---|---|
| | | consumption of | consumption of | |
| Environ- | | the conventional | the T-shaped | Power |
| mental | | heat dissipation | heat dissipation | consumption |
| temperature | CPU | device | device | difference |
| (° C.) | loading | (W) | (W) | (W) |
| 25° C. | idle | 299 | 287 | 11 |
| | 30% | 370 | 357 | 13 |
| | 50% | 415 | 400 | 15 |
| | 100% | 532 | 521 | 10 |
| 30° C. | idle | 309 | 294 | 15 |
| | 30% | 382 | 364 | 18 |
| | 50% | 427 | 407 | 20 |
| | 100% | 538 | 528 | 10 |
| 35° C. | idle | 318 | 303 | 15 |
| | 30% | 393 | 372 | 21 |
| | 50% | 439 | 416 | 22 |
| | 100% | 551 | 536 | 14 |

In above table, in the cases that the environment temperatures are 25° C., 30° C., and 35° C., and the CPU loadings are idle, 30%, 50%, and 100%, the power consumptions of the conventional heat dissipation device are higher than that of the heat dissipation device of this embodiment. In comparison, the conventional heat dissipation device needs the fan, which it is cooperated with, to operate at a higher speed and thus consuming more energy, but the T-shaped heat dissipation device of this embodiment does not require the fan to operate at a higher speed to achieve the same effect. Therefore, the heat dissipation device of this embodiment is more efficient and helps to save energy.

The casing 400 covers a side of the first heat dissipation component 100 and a side of the second heat dissipation component 200. The casing 400 has a side wall 403 located at the recesses. In this or another embodiment, there may be a wall, similar to the side wall 403, located at a side of the second heat dissipation component 200 away from the first heat dissipation component 100. The side walls 403 of the casing 40 increase the structural strength of the heat dissipation device to prevent the heat dissipation device from being deformed while subjected to impact, thereby avoiding affecting the heat dissipation efficiency of the heat dissipation device due to the deformation issue.

The casing 400 has a plurality of through holes 401 respectively located at the recesses. The first through holes 401 penetrate through the casing 400 and are configured for the insertion of fasteners (e.g., screws) for the purpose of fixing the heat dissipation device at a place nearby the CPU. The casing 400 has a second through hole 402 corresponding to the heat pipes 300. The second through hole 402 exposes parts of the heat pipes 300, such that heat on the heat pipes 300 can be partially dissipated from the second through hole 402.

According to the heat dissipation device as discussed above, the heat dissipation device includes a first heat dissipation component, at least one second heat dissipation component and at least one heat pipe. The heat pipe is connected to the first heat dissipation component and the second heat dissipation component. The first heat dissipation component is correspondingly disposed on a side of the CPU. In the disclosure, since the heat pipe is connected to the first heat dissipation component and the second heat dissipation component, such that the heat pipe is able to transmit at least part of heat on the first heat dissipation component to the second heat dissipation component, increasing the heat dissipation area of the heat dissipation device and thereby increasing the heat dissipation efficiency of the heat dissipation device to the central process unit. Therefore, there is no need to speed up the fan and thus saving energy.

Furthermore, the casing of the heat dissipation device has the side walls located at recesses of the first heat dissipation component, such that the side walls of the casing increase the structural strength of the heat dissipation device to prevent the heat dissipation device from being deformed while subjected to impact, thereby avoiding affecting the heat dissipation efficiency of the heat dissipation device due to the deformation issue.

The descriptions of the terms “first”, “second” and the like in the specification are merely used to distinguish between the various components, elements, steps, etc. in the specification, and are not intended to represent logical relationship or order relationship between them.

The above embodiments were chosen and described in order to best explain the principles of the disclosure and its practical applications, but the present disclosure is not limited thereto. For those skilled in art, without departing from the scope of the present disclosure, they can utilize the disclosure and various embodiments with various modifications as are suited to the particular use contemplated. Therefore, the simple modifications and equivalent changes made from the above embodiments of the disclosure according to the spirit of the disclosure still fall within the scope of the disclosure. It is intended that the scope of the disclosure be defined by the following claims and their equivalents.

What is claimed is:

1. A heat dissipation device, configured to dissipate heat generated by a central processing unit, comprising:
a first heat dissipation component;
at least one second heat dissipation component; and
at least one heat pipe, wherein the at least one heat pipe is connected to the first heat dissipation component and the at least one second heat dissipation component, the first heat dissipation component is configured to be correspondingly disposed at a side of the central processing unit.

2. The heat dissipation device according to claim 1, wherein the first heat dissipation component comprises:
a main heat dissipation part, comprises a plurality of first fins which are arranged side by side along a thickness direction thereof; and
at least one sub heat dissipation part, comprises a plurality of second fins which are arranged side by side along a thickness direction thereof;
wherein, the at least one sub heat dissipation part is fixed on the main heat dissipation part, and the thickness direction of the main heat dissipation part is the same as the thickness direction of the at least one sub heat dissipation part.

3. The heat dissipation device according to claim 2, wherein the quantity of the at least one sub heat dissipation part is four, the four sub heat dissipation parts are arranged in two groups respectively disposed at two opposite sides of the main heat dissipation part in an arrangement direction of the first fins, and the sub heat dissipation parts in each of the groups are spaced apart from each other.

4. The heat dissipation device according to claim 3, wherein the main heat dissipation part has two opposite ends on an extension direction of the plurality of first fins, two of the sub heat dissipation parts located at the same side of the main heat dissipation part are located between the two opposite ends of the main heat dissipation part, and there are three recesses at each side of the main heat dissipation part and defined by the main heat dissipation part and two of the sub heat dissipation parts.

5. The heat dissipation device according to claim 4, wherein the at least one second heat dissipation component comprises a plurality of third fins arranged side by side along a thickness direction of the second heat dissipation component.

6. The heat dissipation device according to claim 5, wherein the at least one heat pipe has two ends respectively connected to the first heat dissipation component and the at least one second heat dissipation component.

7. The heat dissipation device according to claim 6, further comprising a casing, wherein the first heat dissipation component and the at least one second heat dissipation component are disposed on a same surface of the casing.

8. The heat dissipation device according to claim 7, wherein when the casing has k ends, the quantity of the at least one second heat dissipation component is (k−1); the first heat dissipation component and the (k−1) second heat dissipation components are respectively disposed on the (k) ends of the casing, and the at least one heat pipe is located among the (k) ends of the casing; wherein k≥2.

9. The heat dissipation device according to claim 8, wherein the casing covers a side of the first heat dissipation component and a side of the at least one second heat dissipation component, the casing has side walls respectively located at the recesses and a side of the at least one second heat dissipation component away from the first heat dissipation component.

10. The heat dissipation device according to claim 9, wherein the casing has a plurality of first through holes respectively located at recesses, the plurality of first through holes penetrate through the casing, the plurality of first through holes are configured for inserting fasteners to fix the heat dissipation device at a place nearby the central processing unit.
